(19) United States
(12) Patent Application Publication
(10) Pub. No.: US 2025/0112100 A1
(43) Pub. Date: Apr. 3, 2025

(54) DIE EMBEDDED IN GLASS LAYER WITH TWO-SIDE CONNECTIVITY

(71) Applicant: Intel Corporation, Santa Clara, CA (US)

(72) Inventors: Robert May, Chandler, AZ (US); Hiroki Tanaka, Gilbert, AZ (US); Tarek Ibrahim, Mesa, AZ (US); Lilia May, Chandler, AZ (US); Jason Gamba, Gilbert, AZ (US); Benjamin Duong, Phoenix, AZ (US); Brandon Marin, Gilbert, AZ (US); Srinivas Pietambaram, Chandler, AZ (US); Gang Duan, Chandler, AZ (US); Suddhasattwa Nad, Chandler, AZ (US); Jeremy Ecton, Gilbert, AZ (US)

(73) Assignee: Intel Corporation, Santa Clara, CA (US)

(21) Appl. No.: 18/375,209

(22) Filed: Sep. 29, 2023

(51) Int. Cl. H01L 23/29; H01L 23/00; H01L 23/31; H01L 25/00; H01L 25/065

(52) U.S. Cl. CPC H01L 23/291; H01L 24/19; H01L 24/20; H01L 24/24; H01L 24/25; H01L 25/0652; H01L 25/50; H01L 23/3121; H01L 2224/19; H01L 2224/22505; H01L 2224/2505; H01L 2225/06541; H01L 2924/1431; H01L 2924/1434

(57) ABSTRACT

An IC die package includes first and second IC die on a first surface of a glass layer, a bridge under the first and second IC die within an opening in the glass layer, and first and second package conductive features on a second surface of the glass layer opposite the first side. First interconnects comprising solder couple the bridge with the first and second IC die. Second interconnects excluding solder couple the first and second IC die with vias extending through the glass layer to the first package conductive features. Third interconnects excluding solder couple the bridge with the second package conductive features. The bridge couples the first and second IC die with each other, and the first and second IC die with the second package conductive features. A pitch of conductive features in the first interconnects is less than a pitch of conductive features in the second interconnects.

### BACKGROUND

In electronics manufacturing, integrated circuit (IC) packaging is a stage of semiconductor device fabrication in which an IC that has been monolithically fabricated on a chip (or die) is assembled into a “package” that can protect the IC chip from physical damage. The package can also communicatively connect the IC chip to other packaged IC chips and/or a scaled host component, such as a package substrate, or a printed circuit board. Multiple IC chips can be co-assembled, for example, into a multi-die package (MCP).

In some multi-die package architectures, two IC chips may communicate with each other using a bridge. However, as IC technology evolves, the scale of features on IC devices, such as the pitch between contacts on chips, becomes smaller. As contact pitches become smaller, it can be difficult to align and bond an IC chip to a bridge. Manufacturing difficulties can result in reduced yields.

### BRIEF DESCRIPTION OF THE DRAWINGS

The subject matter described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Views referred to as “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure. Further, where considered appropriate, reference labels have been repeated among the figures to indicate corresponding or analogous elements. In the figures:

FIGS. 1A and 1B illustrate a flow diagram of methods for forming an IC device package including first and second IC die on a first surface of a glass layer, a bridge IC device under the first and second IC die within an opening in the glass layer, and first and second package conductive features on a second surface opposite the first surface, in accordance with some embodiments;

FIGS. 2A through 2M illustrate views of a glass preform evolving to include first and second IC die on a first surface of glass, a bridge IC device under the first and second IC die within an opening in the glass, and first and second package conductive features on a second surface opposite the first surface as selected operations in the methods illustrated in FIG. 1A are performed, in accordance with some embodiments;

FIG. 3 illustrates a cross-sectional view of an IC device package structure comprising first and second IC die on a first surface of a glass layer, a bridge IC device under the first and second IC die within an opening in the glass layer, and first and second package conductive features on a second surface opposite the first surface, wherein the bridge couples the first and second IC die with each other, and the first and second IC die with the second package conductive features, in accordance with some embodiments;

FIG. 4 illustrates a system including the IC device package structure illustrated in FIG. 3 attached to a host component with solder features, in accordance with some embodiments;

FIG. 5 illustrates a mobile computing platform and a data server machine employing one or more of IC device package structures illustrated in FIG. 3 and/or one or more of the systems illustrated in FIG. 4, in accordance with some embodiments; and

FIG. 6 is a functional block diagram of an electronic computing device employing one or more of IC device package structures illustrated in FIG. 3 and/or one or more of the systems illustrated in FIG. 4, in accordance with some embodiments.

### DETAILED DESCRIPTION

Embodiments are described with reference to the enclosed figures. While specific configurations and arrangements are depicted and discussed in detail, this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses all possible combinations of one or more of the associated listed items.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct physical contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the specific context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

In some multi-die package architectures, two IC chips may communicate with each other using a bridge. However, as IC technology evolves, the scale of features on IC devices, such as the pitch between contacts on chips, becomes smaller. As contact pitches become smaller, it can be difficult or impossible to align and bond an IC chip to a bridge. For example, a bridge can be embedded in a substrate. Two IC dies on a first side of the substrate can be connected to the bridge by interconnects that include solder and which are formed using thermocompression bonding (TCB) in a region adjacent to the bridge (“bridge region”). The two IC die can also be connected to conductive contacts on a second side of the substrate by vias extending through the substrate. The two IC die may be connected to these vias by interconnects that include solder and which are formed using TCB in “core” regions. The pitch of conductive contacts in the bridge region can be smaller than the pitch of conductive contacts in core regions. Due to the tight alignment tolerances for the conductive contacts and the critical dimensions of the vias, it can be difficult to manufacture IC device package structures when the pitch of conductive contacts is small, for example, when the pitch of conductive contacts in the bridge region is below 60 microns. Manufacturing difficulties can result in reduced yields. Another factor contributing to manufacturing difficulties is that the TCB window is reduced by alignment/true position requirements, which are partially driven by the need to simultaneously form solder joints in both the core and bridge regions.

Integrated circuit (IC) device package structures that include a glass layer, first and second IC die on a first surface of the glass layer, a bridge IC die under the first and second IC die within an opening in the glass layer are described herein. The glass layer may be a core, substrate, or other layer in the IC device package structure. The embodiments described herein may provide advantages related to manufacturing. Specifically, the first and second IC die include conductive features with a small pitch in the bridge region, e.g., 60 microns or less. The first and second IC die also include conductive features with a larger pitch in the core region. The IC device package structure also includes first and second package conductive features on a second surface opposite the first surface that are coupled with the larger pitch conductive features in the core region. The bridge IC die includes conductive features that pair with the bridge region conductive features of the first and second IC die. Advantageously, conductive features in the bridge region between the bridge and first and second IC die may be aligned and bonded without concern for precise alignment of the larger pitch conductive features in the core region or solder bridging. This is because conductive features in the core region are bonded at a later manufacturing stage in an electroplating process without solder. The embodiments described herein may advantageously result in improved manufacturing yields.

In various embodiments, first interconnects comprising solder couple the bridge IC die with the first and second IC die. Second interconnects excluding solder couple the first and second IC die with first vias extending through the glass layer to first package conductive features. The bridge IC die couples the first and second IC die with each other, and may couple the first and second IC die with second package conductive features. A pitch of conductive features in the first interconnects is less than a pitch of the conductive features in the second interconnects. In embodiments, a pitch of conductive features in the first interconnects is less than 60 microns. In embodiments, a pitch of conductive features in the second interconnects is 80 microns or greater.

In various embodiments, third interconnects excluding solder couple the bridge IC die with the second package conductive features. In addition, second vias extend from conductive features of the third interconnects through a dielectric layer to first package conductive features. A pitch of conductive features in the first interconnects is less than a pitch of the conductive features in the third interconnects. In embodiments, a pitch of conductive features in the third interconnects is 80 microns or greater. An advantage of the embodiments described herein is that the bridge IC die electrically couples the first and second IC die with each other by “top” conductive features on a first surface of the bridge, and may also couple the first and second IC die with the second package conductive features by “bottom” conductive features on a second surface of the bridge opposite the first surface. This two-sided connectivity advantageously increases the number of electrical paths from the first and second IC die to other microelectronic components.

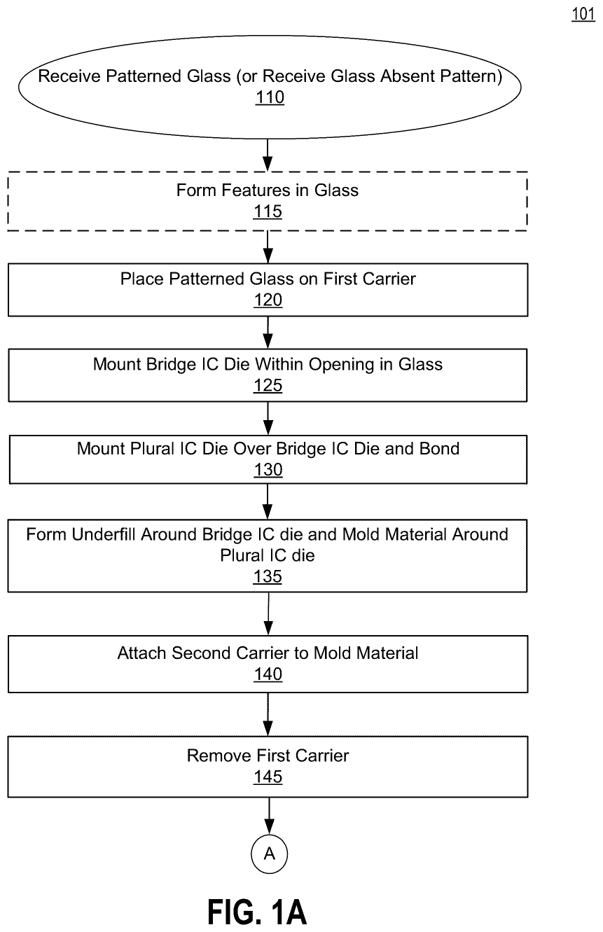

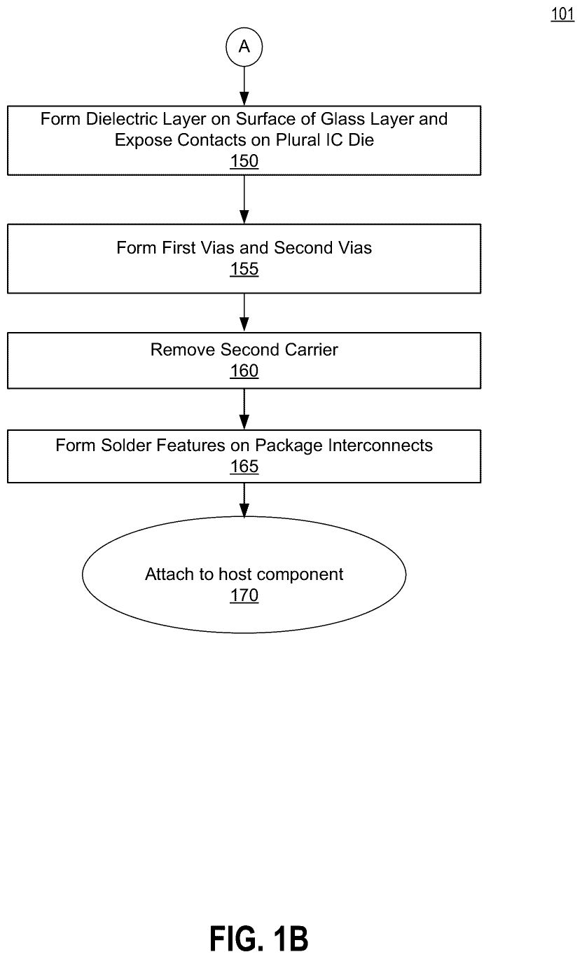

As illustrated in FIGS. 1A and 1B, a variety of fabrication methods may be practiced to form IC device package structures having one or more of the features described herein. FIGS. 1A and 1B illustrate a flow diagram of methods 101 for forming an IC device package structure including first and second IC die on a first surface of a glass layer, a bridge IC die under the first and second IC die within an opening in the glass layer, and first and second package conductive features on a second surface of the glass layer opposite the first side, wherein the bridge IC die couples the first and second IC die with each other in first interconnects comprising solder, and couples the first and second IC die with the first package conductive features in second interconnects excluding solder, in accordance with some embodiments. Methods 101 begin at input 110 where a workpiece including a thickness of glass is received. The workpiece may be prepared upstream of methods 101 and may be in a large panel format, a wafer format, or the like. The workpiece received at input 110 may be patterned with a plurality of holes, as described below, or the workpiece may not be patterned, e.g., holes may be absent from the workpiece. The holes may be of a variety and shapes and size, and may alternatively be referred to as “openings” herein.

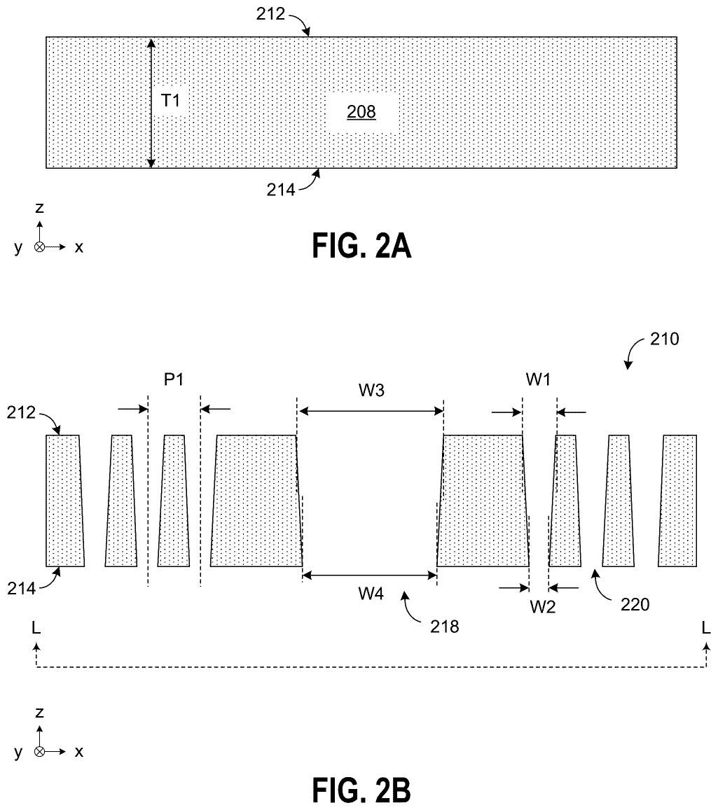

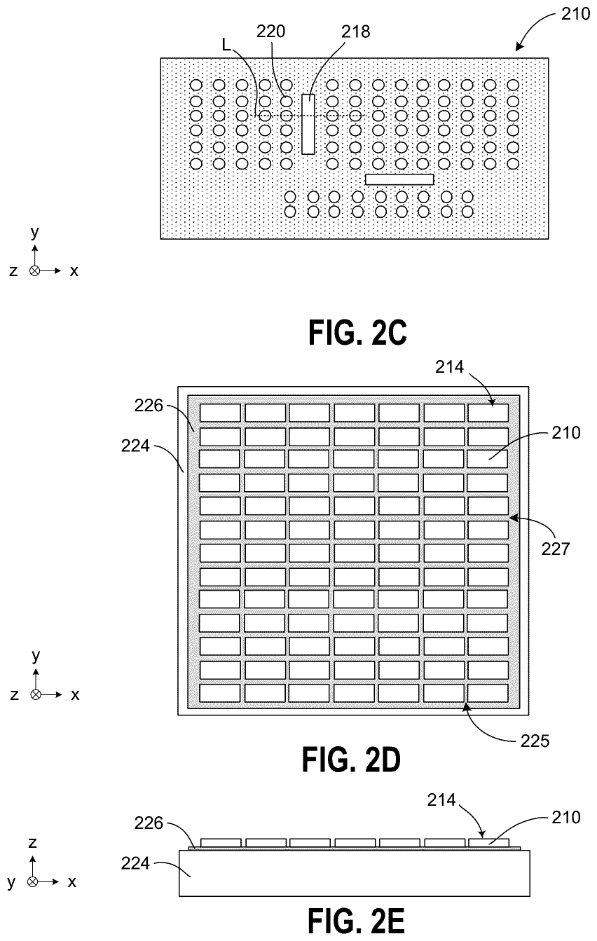

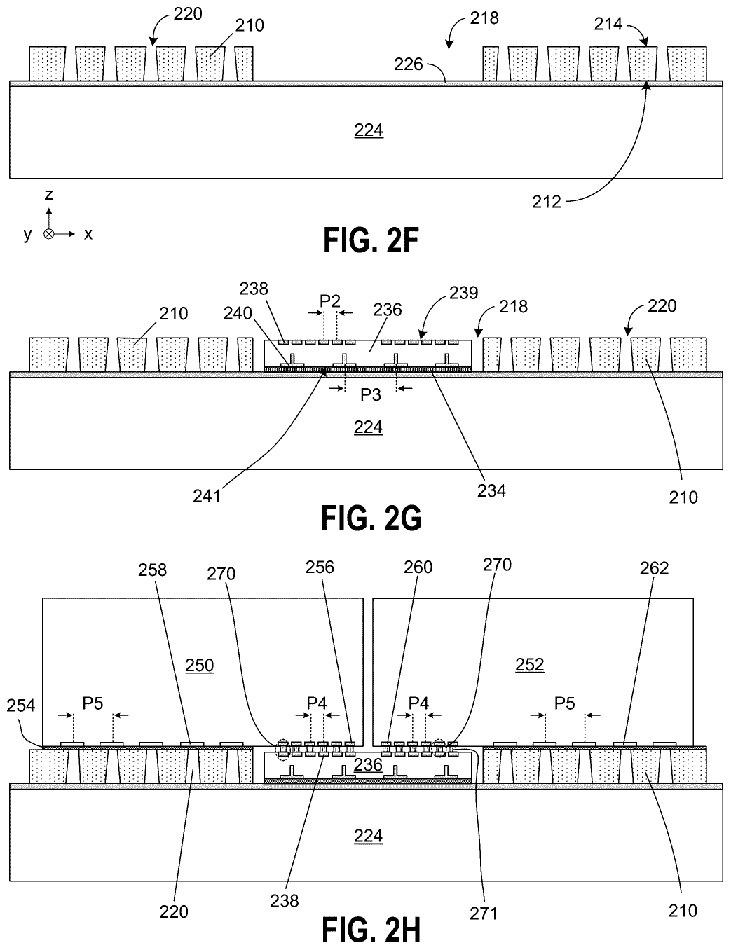

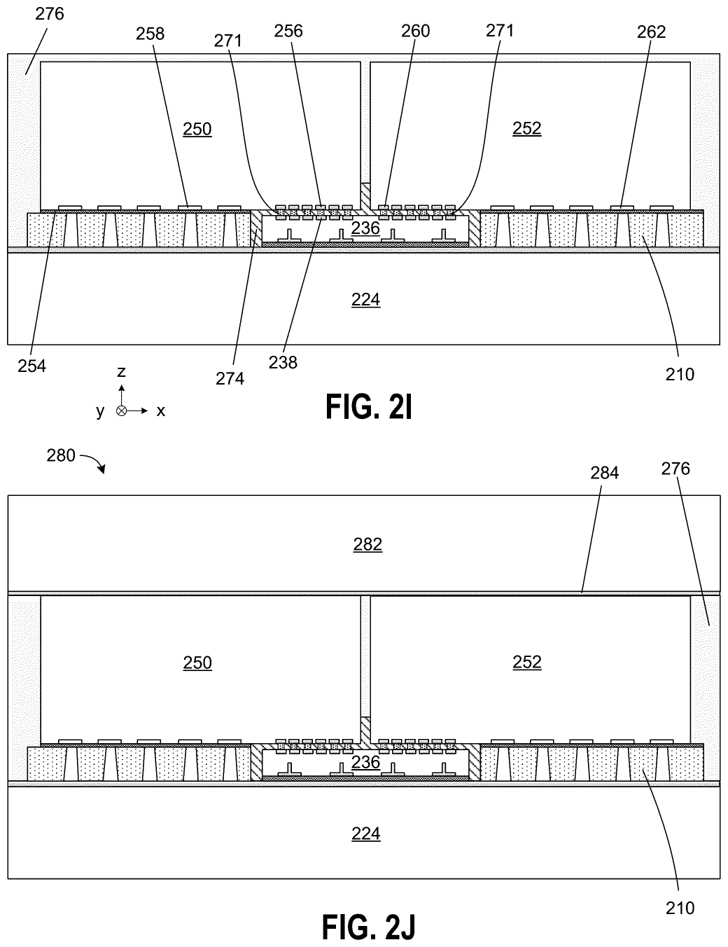

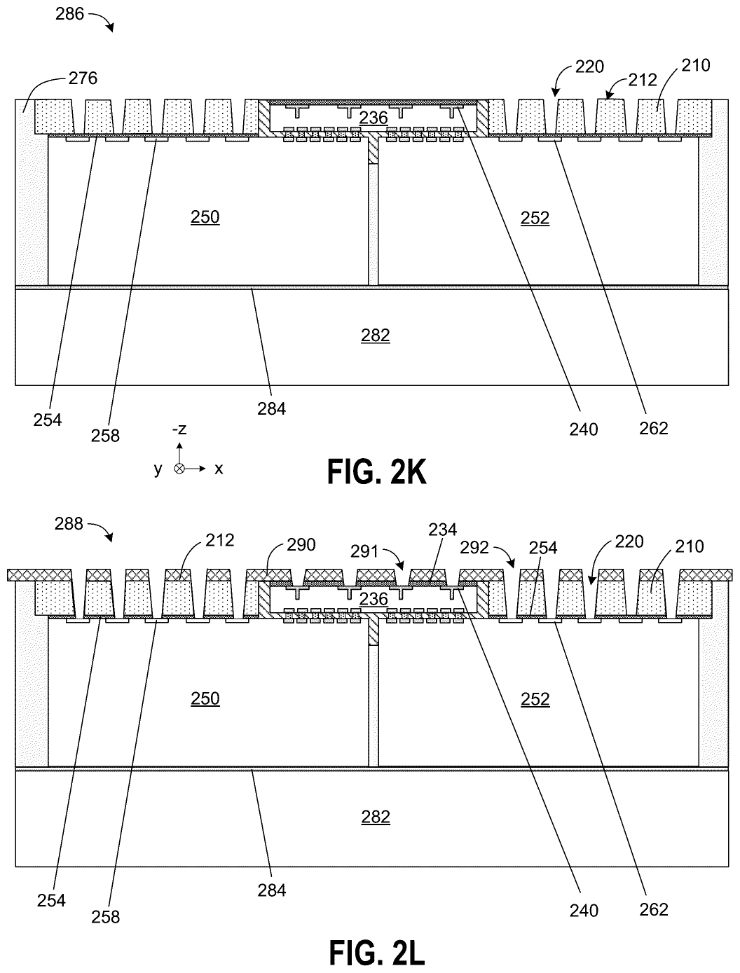

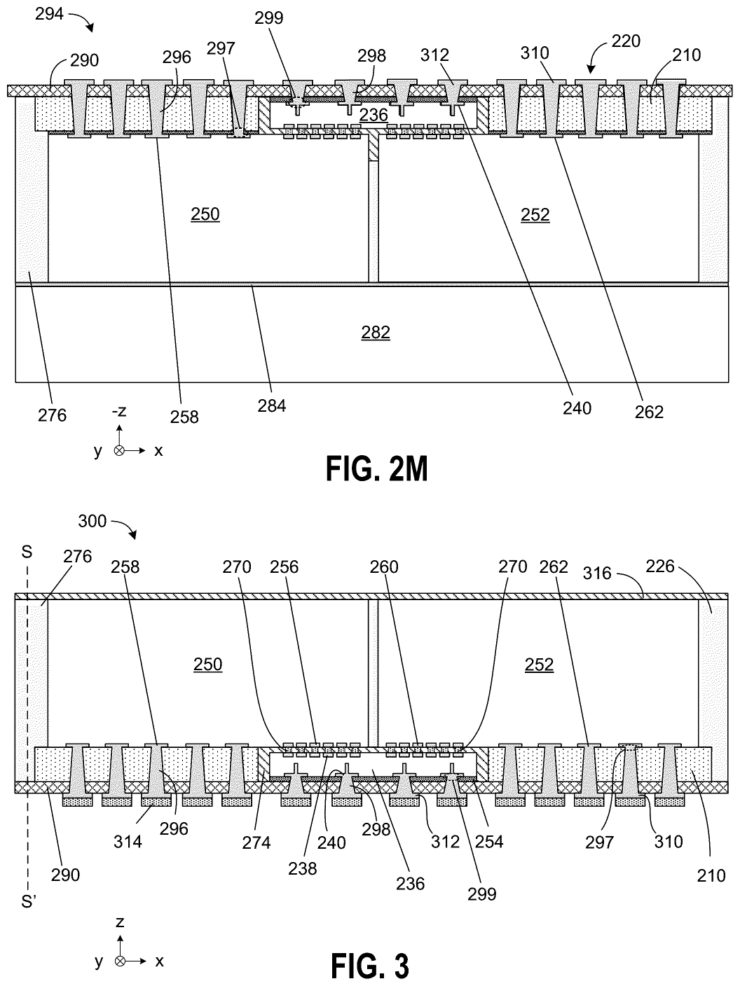

FIG. 2A is a cross-sectional view of an exemplary workpiece including glass 210. Advantages of fabricating IC device package structures upon such a glass are that the flatness and/or thickness control for a preform of glass is superior to that of starting substrates based on organic materials (e.g., epoxy), and the costs can be significantly lower than for monocrystalline materials (e.g., silicon). Glass 210 is a solid bulk material layer that may have been previously formed into any shape suitable for a packaging workpiece, such as rectangular. Glass 210 has a thickness T1 that may vary with implementation, for example to limit warpage while remaining thin enough to permit the formation of through vias at a pitch as small as is enabled by the surface flatness of glass 210. In exemplary embodiments, thickness T1 is advantageously 200 μm to 2000 μm.

Glass 210 is advantageously predominantly silicon and oxygen. In some embodiments, glass 210 comprises at least 23 percent silicon and at least 26 percent oxygen, by weight (i.e., wt. %). Glass 210 may further include one or more additives, such as, Aluminum, Boron, Magnesium, Calcium, Barium, Tin, Sodium, Potassium, Strontium, Phosphorus, Zirconium, Lithium, Titanium, or Zinc. In some embodiments where glass 210 comprises at least 23 wt. % Si and at least 26 wt. % O, glass 210 further comprises at least 5 wt. % Al. Additives within glass 210 may form suboxides (A2O) monoxides (AO), binary oxides (AO2), ternary oxides (ABO3), and mixtures thereof. For example, glass 210 may comprise AlOx (e.g., Al2O3), BOx (e.g., B2O3), MgOx (e.g., MgO), CaOx (e.g., CaO), SrOx (e.g., SrO), BaOx (e.g., BaO), SnOx (e.g., SnO2), NaOx (e.g., Na2O), KOx (e.g., K2O), POx (e.g., P2O3), ZrOx (e.g., ZrO2), LiOx (e.g., Li2O), TiOx (e.g., TiO2), or ZnOx (e.g., ZnO2). Depending on chemical composition, glass 210 may therefore be referred to as silica, fused silica, aluminosilicate, borosilicate, or alumino-borosilicate, for example.

Glass 210 is advantageously a bulk material of substantially homogeneous composition in contrast to a composite material that may merely comprise glass fillers and/or fibers. Although glass 210 is substantially amorphous in some embodiments, glass 210 may also have other morphology or microstructure, such as polycrystalline (e.g., nanocrystalline).

Although not depicted, one or more material layers may clad either or both of the first surface 212 or second surface 214 of glass 210 so that glass 210 is a bulk or core layer of a multi-layered substrate. Exemplary cladding materials include inorganic materials such as silicon nitride (SiNx) or silicon oxynitride (SiOxNy). In other embodiments, a silicon layer (polycrystalline or monocrystalline) may clad one or both sides of glass 210. Organic material layers, such as polymer dielectric materials, may also clad one or more sides of glass 210. Hence, while glass 210 is advantageously substantially free of organic materials (e.g., no adhesives, etc.), a workpiece may include organic material within a substrate stack that includes glass 210.

Returning to FIG. 1A, methods 101 continue at block 115 where features (e.g., through holes) are optionally formed in un-patterned glass 208. The features may be fabricated with any process known to be suitable for bulk glass. In some embodiments, block 115 entails laser ablation, a glass etch process (laser-assisted, or otherwise), or any other technique known to be suitable for forming features through a thickness of the workpiece received at input 110 at a desired diameter and feature pitch. Example features include holes and openings.

FIG. 2B illustrates an example of patterned glass 210. The shown embodiment is indicative of a substantially single-sided asymmetrical hole formation process resulting in opening 218 and through holes 220. The opening 218 and through holes 220 are asymmetric about a longitudinal z-axis (demarked in dashed line) with tapered (e.g., x dimension) lateral widths that are largest at first surface 212 and smallest at second surface 214 of glass 210. The widths W1 and W2 of through holes 220 at first and second surfaces 212, 214, respectively, may vary with implementation. However, in some examples the largest width W1 is 100 μm, or less, and advantageously 50 μm, or less. The aspect ratio (T1:largest width W) of through holes 220 may also vary with an exemplary range being 4-20. In some embodiments where glass 210 has a thickness T1 of at least 500 μm, through holes 220 have a minimum lateral pitch P1 that is 200 μm, or less, and advantageously 100 μm, or less. The widths W3 and W4 of opening 218 at first and second surfaces 212, 214, respectively, may vary with implementation. In a subsequent operation, opening 218 will receive a bridge IC die and width W4 is at least marginally larger than the width of the bridge IC die. While only one opening 218 is shown, multiple openings 218 may be formed in glass 210 to receive multiple IC die. Although the asymmetrical taper illustrated in FIG. 2B is indicative of a one-sided through-hole (and opening) formation process, symmetrical two-sided though hole embodiments are also possible. In addition, widths W1 and W2 may be substantially equal, and/or widths W3 and W4 may be substantially equal, such that sidewalls of the through-holes and/or opening are substantially straight and perpendicular to surfaces 212, 214. Also, although only through holes are illustrated in FIG. 2B, blind holes or recesses that do not pass entirely through thickness T1 may also be fabricated into one or more of first surface 212 or second surface 214. Through holes 220 may have any shape within a plan view (x-y) plane, such as substantially circular, rectangular, or any other polygon. The plan view shape may vary over thickness T1. Similarly, opening 218 may have any shape within a plan view plane, e.g., rectangular or square. FIG. 2C illustrates, in plan view, another example of a workpiece includes glass 210 having two openings 218 and a plurality of through holes 220.

Returning to FIG. 1A, methods 101 continue at block 120 where a patterned glass workpiece is placed on affixed to a handle or carrier. FIG. 2D illustrates a plan view of a plurality of exemplary patterned glass workpieces 210 that have been placed on and affixed to a carrier 224, which may be referred to herein as a first carrier. Carrier 224 may have any suitable composition and be of any suitable thickness, as embodiments herein are not limited in this context. Patterned glass 210 may be affixed to carrier 224 with an adhesive 226. Adhesive 226 may have any suitable composition, as embodiments herein are not limited in this context. Adhesive layer 226 may be referred to as a laser release layer (LRL), and comprise a material that allows carrier 224 to be removed from glass 210 when exposed to light. Example adhesives include thermoplastic or thermoset polymer adhesives. FIG. 2E illustrates a cross-sectional view of the plurality of patterned glass workpieces 210 depicted in FIG. 2D. As shown in FIGS. 2D and 2E, the patterned glass workpieces 210 are separated from one another on a surface of the carrier by “streets” 225, 227. An advantage of embodiments disclosed herein is that IC device packages comprising glass 210 may be singulated without the need to cut through the glass 210, which may minimize crack formation and propagation in of the glass, e.g., SeWaRe type failures. Minimizing glass failures advantageously improves yield of good IC device packages. FIG. 2F illustrates a cross-sectional view of one of the plurality of patterned glass workpieces 210 depicted in FIGS. 2D and 2E.

Returning to FIG. 1A, methods 101 continue at block 125 where an IC die is placed within an opening in a glass layer and attached. Although the IC die placed at block 125 is a bridge IC die, in other embodiments, the IC die may be any type of IC die, e.g., a die comprising logic or memory circuitry. FIG. 2G illustrates a bridge IC die 236 that has been placed in opening 218 and affixed to LRL 226 on carrier 224. Bridge IC die 236 includes a top side 239 and a bottom side 241. (As mentioned, the terms “top” and “bottom” are used merely to facilitate the description and are not intended to be limiting.) Bridge IC die 236 may be placed such that bottom side 241 is proximate carrier 224. Bridge IC die 236 may be mechanically coupled to adhesive layer (LRL) 226 on carrier 224 by adhesive layer 234 (e.g., a die-attach film (DAF)) between bottom side 241 and carrier 224. In some examples, adhesive layer 234 may include acrylic or epoxy resins, with or without fillers, such as silicon (Si). Top bridge conductive features 238 are on the top side 239 and bottom bridge conductive features 240 are on the bottom side of bridge IC die 236. Top and bottom bridge conductive features 238, 240 may comprise any suitable conductive material, such as copper (Cu). In some embodiments, top and bottom bridge conductive features 238, 240 may include a surface finish (not shown in FIG. 2G) to protect the material of the conductive feature from corrosion. The surface finish may include nickel, palladium, gold, or combination thereof. Top and bottom bridge conductive features 238, 240 may be recessed in, flush with, or extending away from top and bottom sides 239, 241, respectively. Bridge IC die 236 may have a z-height that is close to but less than the z-height of glass layer 210. For example, the combined height of bridge IC die 236, adhesive layer 234, and solder (not shown in FIG. 2G) on top side conductive features may be substantially equal to the height of glass layer 210.

Top bridge conductive features 238 on top side 239 may have a pitch P2. For example, the pitch P2 of top bridge conductive features 238 may be less than about 60 microns. In some examples, pitch P2 of top bridge conductive features 238 may be between 20 and 60 microns. For example, the pitch P2 of top bridge conductive features 238 may be about 25, 30, 35, 40, 45, 50, or 55 microns. The bottom bridge conductive features 240 on the bottom side of bridge IC die 236 may have a pitch P3. For example, the bottom bridge conductive features 240 may have a pitch P3 that is about 80 microns or greater. In some examples, pitch P3 of bottom bridge conductive features 238 may be 80 to 150 microns.

Top bridge conductive features 238 and bottom bridge conductive features 240 may be used to electrically couple bridge IC die 236 to one or more other microelectronic components. The bridge IC die 236 may include conductive pathways, such as lines and vias. The conductive pathways may electrically couple one of the top bridge conductive features 238 with another of the top bridge conductive features 238. Similarly, the conductive pathways may electrically couple one of the bottom bridge conductive features 240 with another of the bottom bridge conductive features 240. In addition, the conductive pathways may electrically couple one of the top bridge conductive features 238 with a bottom bridge conductive feature 240. The bridge IC die 236 may comprise only conductive pathways interconnecting various ones of the top and bottom bridge conductive features 238, 240, i.e., bridge IC die 236 may be a “passive” bridge. In some alternative embodiments, bridge IC die 236 may be an “active” component and may contain circuitry comprising one or more active devices, e.g., transistors. In alternative embodiments, bridge IC die 236 may include logic and/or memory circuitry. The bridge IC die 236 may include a semiconductor material, e.g., silicon. The conductive pathways within bridge IC die 236 may be used to conduct logic or power signals. The −x and −y dimensions of bridge IC die 236 may take any suitable values.

Returning to FIG. 1A, methods 101 continue at block 130 where two or more IC die are placed over the glass layer and bonded to the bridge IC die within an opening in the glass. FIG. 2H illustrates first IC die 250 and second IC die 252 that have been placed over glass layer 210, and bonded to bridge IC die 236 within opening 218. In some examples, more than two IC die may be placed over the glass layer and bonded to the bridge IC die 236, as FIG. 2H is simply one illustration.

First IC die 250 includes first conductive features 256 and second conductive features 258 on a side of the die. First IC die 250 is placed such that the side of the die having the first and second conductive features 256, 258 is proximate to glass layer 210. First IC die 250 is placed so that first conductive features 256 are adjacent to and aligned with respective top bridge conductive features 238 on bridge die 236. In addition, first IC die 250 is placed so that second conductive features 258 are adjacent to and aligned with respective holes 220 in glass layer 210. Similarly, second IC die 252 includes third conductive features 260 and fourth conductive features 262 on a side of the die. Second IC die 252 is placed such the side of the die having the third and fourth conductive features 260, 262 is proximate to glass layer 210. Second IC die 252 is placed so that third conductive features 260 are adjacent to and aligned with respective top bridge conductive features 238 on bridge die 236. In addition, second IC die 252 is placed so that fourth conductive features 262 are adjacent to and aligned with respective holes 220 in glass layer 210. The location of first conductive features 256 and third conductive features 260 may be referred to as a “bridge” region. The location of second conductive features 258 and fourth conductive features 262 may be referred to as a “core” region.

As may be seen in FIG. 2H, first conductive features 256 of first IC die 250 are aligned with and attached to particular ones of top bridge conductive features 238. First conductive features 256 and top bridge conductive features 238 are coupled at first interconnects 270, which comprise solder 271. First conductive features 256 and top bridge conductive features 238 may be coupled in a thermocompression bonding (TCB) process. Similarly, third conductive features 260 of second IC die 252 are aligned with and attached to other ones of top bridge conductive features 238. Third conductive features 260 of second IC die 252 are coupled at first interconnects 270, which comprise solder 271. Third conductive features 260 of second IC die 252 may be coupled in a TCB process. First IC die and second IC die are electrically coupled with IC bridge die 236 by first interconnects 270. In addition, first IC die 250 and second IC die 252 may be mechanically coupled to glass layer 210 by adhesive layer 254 between respective sides of first and second IC die 250, 252 having the shown conductive features (256 and 258, or 260 and 262 and glass layer 210. The adhesive layer 254 may comprise any suitable adhesive, such as acrylic or epoxy resins.

An advantage of embodiments disclosed herein is a wider TCB assembly window as compared with a configuration in which an IC die having first and second set of conductive features is to be attached with solder to conductive features on a top surface of a bridge die and, simultaneously, attached with solder to additional conductive features of a layer (e.g., glass, organic dielectric) on a surface coplanar with the bridge die top surface. Advantageously, the positions of first and second die may be adjusted so that first and third conductive features 256, 260 align with top bridge conductive features 238 without concern for solder bridging at second and fourth conductive features 258, 262. At block 130, where two or more IC die are bonded to the bridge IC die, second and fourth conductive features 258, 262 are positioned so that second and fourth conductive features 258, 262 are adjacent to holes 220. At block 130, holes 220 may be empty, e.g., the holes have not yet been metallized.

With reference to first IC die 250, first conductive features 256 may have a pitch P4 and second conductive features 258 may have a pitch P5. With reference to second IC die 252, third conductive features 260 may have the pitch P4 and fourth conductive features 262 may have the pitch P5. In an example, the pitch P4 may be less than about 60 microns, and the pitch P5 may be about 60 microns or greater. In some examples, the pitch P4 may be in a range between 20 and 60 microns, and the pitch P5 may be in a range between 80 and 150 microns. In various embodiments, the first and third conductive features 256, 260 have a pitch that is less than a pitch of the second and fourth conductive features 258, 262. In some embodiments, the first and third conductive features 256, 260 have a pitch that is less than about 60 microns, e.g., in a range between 20 and 60 microns. In some embodiments, the second and fourth conductive features 258, 262 have a pitch that is about 60 microns or greater, e.g., in a range between 80 and 150 microns. While the first and third conductive features 256, 260, and the second and fourth conductive features 258, 262 are illustrated as having equal pitches, this is not essential. In some embodiments, the respective pitches of the first and third conductive features 256, 260 may be different. In addition, in some embodiment the respective pitches of the second and fourth conductive features 258, 262 may be different.

Conductive features 256, 258 of first IC die 250 and conductive features 260, 262 of second IC die 252 may comprise any suitable conductive material, such as copper (Cu). In some embodiments, conductive features 256, 258, 260, and 262 may include a surface finish (not shown in FIG. 2H) to protect the material of the conductive feature from corrosion. The surface finish may include nickel, palladium, gold, or combination thereof. Conductive features 256, 258, 260, and 262 may be recessed in, flush with, or extending away from the side of the IC die.

First IC die 250 and second IC die 252 may include conductive pathways (e.g., lines and vias) to conductive features of the respective die, e.g., conductive features 256, 256, and 260, 262. First and second IC die 250, 252 may include conductive pathways to circuitry (not shown) within the respective die. First and second IC die 250, 252 may also include conductive features in addition to the shown conductive features 256, 256, and 260, 262, which may be on a same or different side of the shown conductive features. First and second IC die 250, 252 may include a semiconductor material, e.g., Si. First and second IC die 250, 252 may be “active” components comprising active devices (e.g., transistors), while in other embodiments, these dies may be a “passive” component in that it does not contain one or more active devices. In some embodiments, one or both of first and second IC die 250 may comprise circuitry to perform any desired functionality. For example, one or both of first and second IC die 250 may be a logic circuit, a power management integrated circuit, a transmitter, a receiver, a memory controller, a communications controller, a controller, a processor, an application specific integrated circuit (ASIC), or a memory. One or both of first and second IC die 250 may include multiple instances of circuitry to perform any desired functionality, e.g., multiple processor cores.

Referring again to FIG. 1A, methods 101 continue at block 135 where an underfill material is formed around the bridge IC die and mold material around is formed around the two or more IC die. FIG. 2I illustrates an underfill material 274 that has been formed around bridge IC die 236 and a mold material 276 that that has been formed over and around first IC die 250 and second IC die 252. The underfill material 274 may serve several functions. The underfill material 274 may mechanically secure IC bridge die 236 to other components, e.g., glass 210, first IC die 250, and second IC die 252. Underfill material 274 may protect conductive features from corrosion and provide electrical insulation. The underfill material 274 may occupy space between sidewalls of opening 218 in glass 210 and sides of bridge IC die 236 extending in the −z direction. The underfill material 274 may occupy space over bridge IC die 236, including spaces between first interconnects 270, e.g., around solder 271. In addition, as shown in the figure, the underfill material 274 may occupy at least some of the space between sides of first IC die 250 and second IC die 252. Example materials for underfill material 274 include dielectric, epoxy materials that may be applied in a capillary process. The mold material 276 may mechanically secure first IC die 250, and second IC die 252 to other components in the IC package. The mold material 276 may occupy space along sidewalls of first and second IC die 250, 252, extending in the −z direction. The mold material 276 may occupy space over first and second IC die 250, 252. Example materials for mold material 276 include any suitable organic material, such as an epoxy material. Mold material may have a low electrical conductivity, and may be a dielectric. Mold material may comprise a cured (e.g., thermoset) resin or polymer comprising an epoxy or silicone. Mold material may also comprise a variety of fillers. Techniques for encasing an IC device are well known. As one example, heated, molten mold material may be transferred into cavities around and over an IC device. Any suitable methods in the art may be used to form mold material 276 around over the first and second IC die.

Referring again to FIG. 1A, methods 101 continue at block 140 where a carrier is attached to mold material formed over the two or more IC die. FIG. 2J illustrates an IC device assembly 280 in which a carrier 282 been placed on and affixed to mold material 276, which may be referred to herein as a second carrier. Carrier 282 may have any suitable composition and be of any suitable thickness, as embodiments herein are not limited in this context. Carrier 282 may be affixed to mold material 276 with an adhesive 284. Adhesive 284 may have any suitable composition, as embodiments herein are not limited in this context. Adhesive layer 284 may comprise a material that allows second carrier 282 to be easily removed from mold material 276. Adhesive layer 284 may be comprise a material that allows carrier 282 to be removed from glass 210 when exposed to light. Example adhesives include thermoplastic or thermoset polymer adhesives.

Referring again to FIG. 1A, methods 101 continue at block 145 where a first carrier is removed from an IC device assembly. FIG. 2K illustrates an IC device assembly 286 in which the first carrier 224 has been removed from the IC device assembly 280 depicted in FIG. 2J. Bridge IC die 236, first IC die 250, second IC die 252 are inverted in FIG. 2K compared to the depiction in FIG. 2J. Removal of first carrier 224 exposes first surface 212 of glass 210, including holes 220. Removal of first carrier 224 may include an operation to clean surface 212.

Referring to FIG. 1B, methods 101 continue at block 150 where a dielectric layer is formed on a surface of the glass layer of the IC device assembly and surfaces of conductive features on the plural IC die are exposed after formation of the dielectric layer. FIG. 2L illustrates an IC device assembly 288 after a dielectric layer 290 has been formed on first surface 212 of glass layer 210 of the IC device assembly 286 depicted in FIG. 2K. FIG. 2L also illustrates the IC device assembly 288 after portions of dielectric layer 290 over holes 220 have been removed, and after portions of adhesive layer 254 on second conductive features 258 and fourth conductive features 262 (within holes 220) have been removed. Further, FIG. 2L illustrates portions of the dielectric layer 290 over bottom bridge conductive features 240, as well as portions of adhesive layer 234 on bottom bridge conductive features 240, have been removed. The operations at block 150 may be performed in an inverted configuration compared to that of FIG. 2J, though this is not essential.

The dielectric layer 290 may comprise a photoimageable dielectric (PID) material, i.e., a dielectric material that is photoimageable (e.g., etched through exposure to an appropriate type of light). Any suitable type of PID material may be used. The composition of dielectric layer 290 may vary with implementation. In some embodiments, the composition of dielectric layer 290 may include an epoxy or polyimide. Dielectric layer 290 may be formed using a deposition method, such as slit coating or lamination. Dielectric layer 290 may have a thickness in the range of about 10 to 40 microns.

After dielectric layer 290 has been formed, portions of the dielectric layer 290 over holes 220 may be removed. Reference number 292 indicates one instance of where a portion of dielectric layer 290 over a hole 220 has been removed. In addition, portions of the dielectric layer 290 over bottom bridge conductive features 240 may be removed. Reference number 291 indicates one instance of where a portion of dielectric layer 290 over a bottom bridge conductive feature 240 has been removed. Portions of the dielectric layer 290 may be removed using lithography. For example, a mask may be disposed on top of dielectric layer 290, where the mask may have openings corresponding to holes 220 and bottom bridge conductive features 240. Subsequently, an appropriate type of light may be exposed through the openings in the mask to form the openings in the dielectric. The mask then may be removed or etched using an appropriate means. Any other operations associated with a photolithography process may also be performed.

After the dielectric layer 290 has been opened, portions of adhesive layer 254 on second conductive features 258 and fourth conductive features 262 may be removed to expose conductive features 258, 262. In addition, portions of adhesive layer 234 on bottom bridge conductive features 240 may be removed to expose conductive features 240. Adhesive layer 254 and adhesive layer 234 may be removed by any suitable method, such as wet or dry etching.

As described below, conductive vias are formed in holes 220 and in holes corresponding with reference number 291 (over bottom bridge conductive feature 240). An advantage of embodiments described herein is that the holes for these conductive vias may have relatively low aspect ratios. Glass layer 210 may be thinner that it otherwise would be if the bridge die 236 was over glass layer 210, because the bridge die 236 is within opening 218 in glass layer 210. The thinner glass layer 210 in turn permits holes for the conductive vias electrically coupled to conductive features 258, 262 and bottom bridge conductive features 240 be shorter than they otherwise would be. In some embodiments, glass layer 210 have a thickness in the range of 40 to 100 microns, and dielectric layer 290 having a thickness in the range of 2 to 30 microns

Referring again to FIG. 1B, methods 101 continue at block 155 where first vias and second vias are formed. FIG. 2M illustrates an IC device assembly 294 after first vias 296 and second vias 298 are formed. The first vias 296 may be formed by electroplating holes 220 and holes in dielectric layer 290 over second conductive features 258 and fourth conductive features 262 with a metal, e.g., Cu. First vias 296 may be referred to as through-glass vias (TGVs). The first vias 296 may be electrically and mechanically coupled with the second conductive features 258 and fourth conductive features 262 at second interconnects 297. First vias 296 may be in direct conductive feature with second conductive features 258 and fourth conductive features 262. Advantageously, the second interconnects 297 exclude solder.

The second vias 298 may be formed by electroplating the holes in dielectric layer 290 over bottom bridge conductive features 240 with a metal, e.g., Cu. The second vias 298 may be electrically and mechanically coupled with bottom bridge conductive features 240 at third interconnects 299. Second vias 298 may be in direct conductive feature with bottom bridge conductive features 240. Advantageously, the third interconnects 299 exclude solder.

Forming of the first vias 296 may include forming first package conductive features 310, and the forming of the second vias 298 may include forming second package conductive features 312. The first and second package conductive features 310, 312 may be pads, contacts, etc., and may be recessed in, flush with, or extending away from dielectric layer 290.

Referring again to FIG. 1B, methods 101 continue at block 160 where the second carrier is removed. FIG. 3 illustrates an IC device package 300 after second carrier 282 has been removed. IC device package 300 is inverted in FIG. 3 compared to the depiction of IC device assembly 294 in FIG. 2M. An optional backside film 316 may be formed at block 160. Backside film 316 may include copper, nickel, palladium, gold, or other suitable material.

Referring again to FIG. 1B, methods 101 continue at block 165 where solder features may be formed on package conductive features. Still referring to FIG. 3, the IC device package 300 is shown after solder features 314 have been formed on first package conductive features 310 and second package conductive features 312, which may be referred to as passive side bumps (PSBs). Solder features 314 may be solder (e.g., SAC) microbumps, although other interconnect features are also possible.

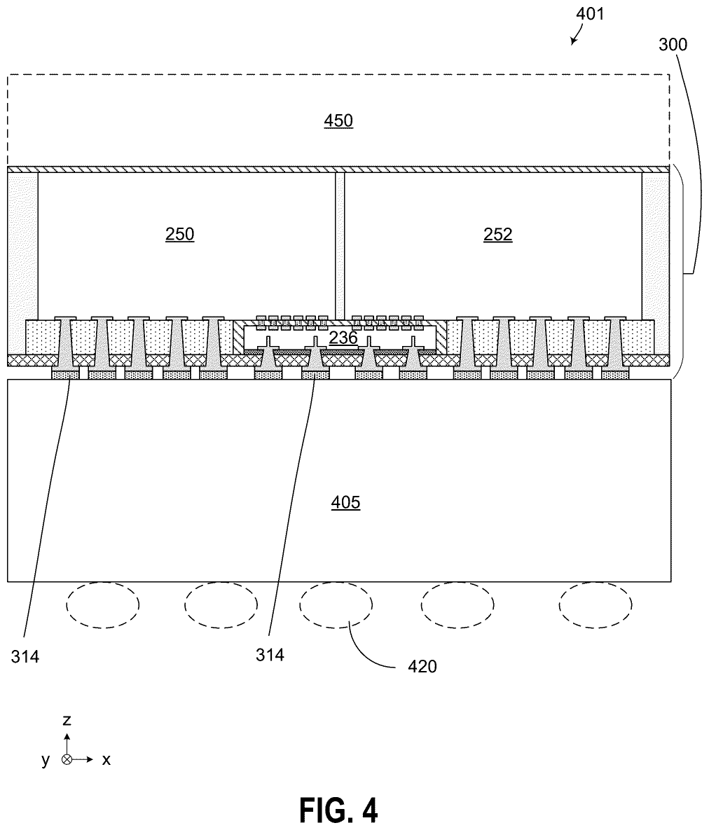

Referring again to FIG. 1B, methods 101 complete at output 170, where the assembled IC device package structure is attached to any suitable host component. FIG. 4 illustrates an exemplary system 401 including one IC device package structure 300 attached to a host component 405 with solder features 314, in accordance with some embodiments.

Operations at output 170 include singulating IC device package structure 300 from other instances that may be present on dielectric layer 290. Referring again to FIG. 2D, a plurality of patterned glass workpieces 210 may be affixed to a carrier 224 with an adhesive 226. Dielectric layer 290 may have dimensions similar to that of adhesive 226 and the patterned glass workpieces 210 shown in FIG. 2D may correspond with instances of IC device package structure 300. Advantageously, IC device package structure 300 may be singulated outside the glass layer 210, such as along line S-S′ as shown in FIG. 3, which may minimize crack formation and propagation in of the glass, e.g., SeWaRe type failures. As may be seen in the figures, singulation line S-S′ passes through backside film 316, mold 276, and dielectric layer 290, but not glass 210. Operations at output 170 may also include testing IC device package structure 300 before attaching it to a host component.

In some embodiments, host component 405 is predominantly silicon. Host component 405 may also comprise one or more alternative materials known to be suitable as interposers or package substrates (e.g., an epoxy preform, cored or coreless laminate board, etc.). Host component 405 may also include a printed circuit board (PCB). Host component 405 may include one or more metallized redistribution levels (not depicted) embedded within a dielectric material. Host component 405 may also include one or more IC die embedded therein.

Host component 405 may include interconnects 420 illustrated in dashed line. Interconnect 420 may comprise any solder (ball, bump, etc.) suitable for a given host board architecture (e.g., surface mount FR4, etc.). Also illustrated in dashed line, one or more heat spreaders and/or heat sinks 450 may be further coupled to IC device package structure 300, which may be advantageous, for example, where IC dies 250, 252 comprise one or more CPU cores or other circuitry of similar power density.

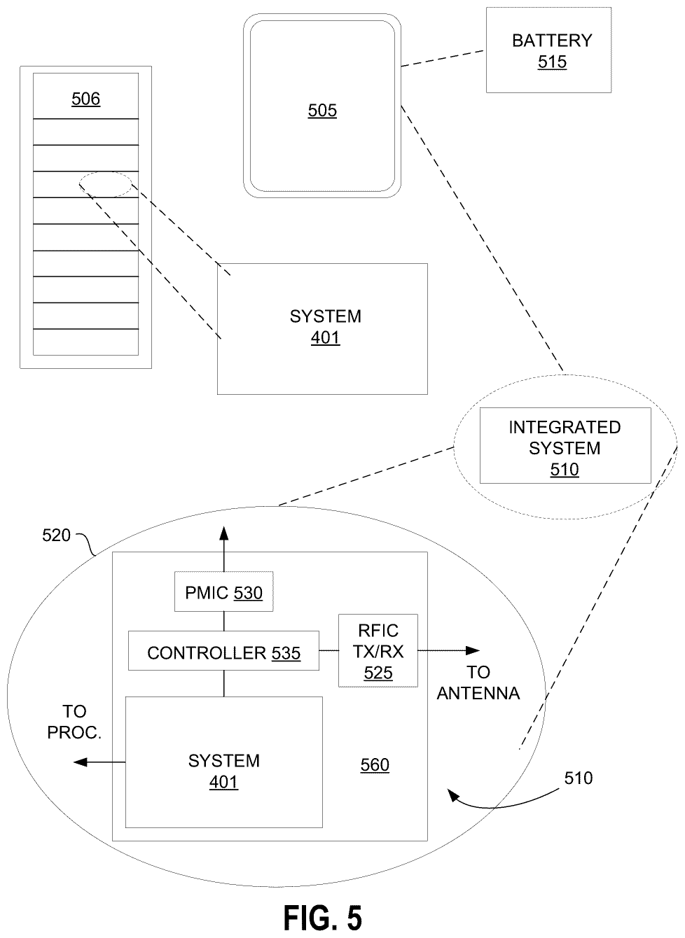

FIG. 5 illustrates a mobile computing platform and a data server machine employing one or more IC device package structures, for example as described elsewhere herein. For example, mobile computing platform 505 or server machine 506 may include IC device package structure device IC package 300 or system 401. Server machine 506 may be any commercial server, for example including any number of high-performance computing platforms disposed within a rack and networked together for electronic data processing, which in the exemplary embodiment includes an IC device package including first and second IC die on a first surface of a glass layer, a bridge IC die under the first and second IC die within an opening in the glass layer, and first and second package conductive features on a second surface of the glass layer opposite the first side, wherein the bridge IC die couples the first and second IC die with each other in first interconnects comprising solder, and couples the first and second IC die with the first package conductive features in second interconnects excluding solder, as described elsewhere herein. The mobile computing platform 505 may be any portable device configured for each of electronic data display, electronic data processing, wireless electronic data transmission, or the like. For example, the mobile computing platform 505 may be any of a tablet, a smart phone, laptop computer, etc., and may include a display screen (e.g., a capacitive, inductive, resistive, or optical touchscreen), a chip-level or package-level integrated system 510, and a battery 515.

Whether disposed within the integrated system 510 illustrated in the expanded view 520, or as a stand-alone package within the server machine 506, the integrated system or server machine includes system 401, wherein the system 401 includes IC device package 300, which includes an IC device package including first and second IC die on a first surface of a glass layer, a bridge IC die under the first and second IC die within an opening in the glass layer, and first and second package conductive features on a second surface of the glass layer opposite the first side, wherein the bridge IC die couples the first and second IC die with each other in first interconnects comprising solder, and couples the first and second IC die with the first package conductive features in second interconnects excluding solder, as described elsewhere herein. System 401 may be further coupled to a host substrate 560, along with, one or more of a power management integrated circuit (PMIC) 530, RF (wireless) integrated circuit (RFIC) 525 including a wideband RF (wireless) transmitter and/or receiver (TX/RX) (e.g., including a digital baseband and an analog front-end module further comprises a power amplifier on a transmit path and a low noise amplifier on a receive path), and a controller 535. PMIC 530 may perform battery power regulation, DC-to-DC conversion, etc., and so has an input coupled to battery 515 and with an output providing a current supply to other functional modules. As further illustrated, in the exemplary embodiment, RFIC 525 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 4G, and beyond.

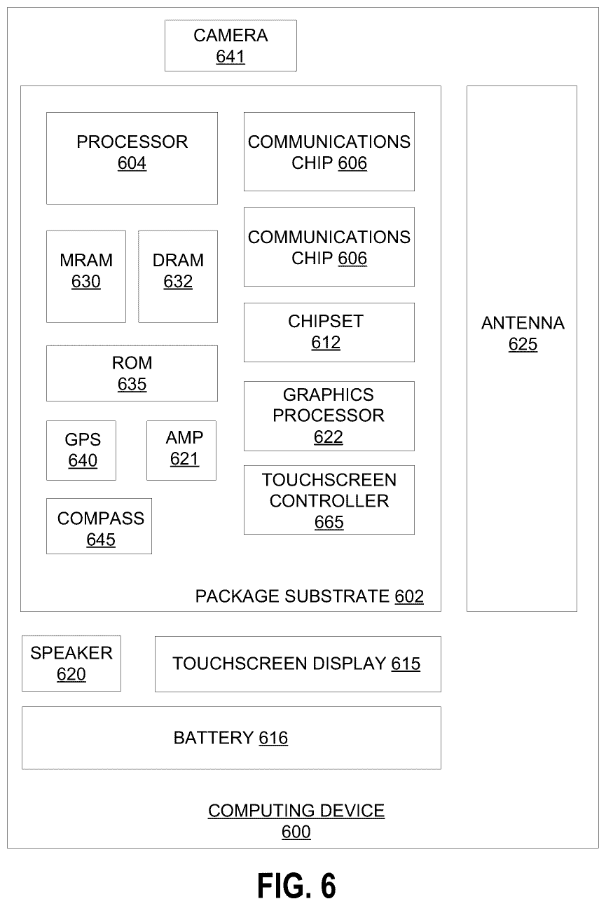

FIG. 6 is a functional block diagram of an electronic computing device 600, in accordance with an embodiment of the present invention. The computing device may include IC device package 300 comprising first and second IC die on a first surface of a glass layer, a bridge IC die under the first and second IC die within an opening in the glass layer, and first and second package conductive features on a second surface of the glass layer opposite the first side, wherein the bridge IC die couples the first and second IC die with each other in first interconnects comprising solder, and couples the first and second IC die with the first package conductive features in second interconnects excluding solder, as described herein. In some embodiments, computing device 600 may include system 401. Device 600 further includes a package substrate 602 hosting a number of components, such as, but not limited to, a processor 604 (e.g., an applications processor). Processor 604 may be physically and/or electrically coupled to package substrate 602. In some examples, processor 604 is within IC device package 300 or system 401, for example, as described elsewhere herein. In general, the term “processor” or “microprocessor” may refer to any device or portion of a device that processes electronic data from registers and/or memory to transform that electronic data into other electronic data that may be further stored in registers and/or memory.

In various examples, one or more communication chips 606 may also be physically and/or electrically coupled to the package substrate 602. In further implementations, communication chips 606 may be part of processor 604. Depending on its applications, computing device 600 may include other components that may or may not be physically and electrically coupled to package substrate 602. These other components include, but are not limited to, volatile memory (e.g., DRAM 632), non-volatile memory (e.g., ROM 635), flash memory (e.g., NAND or NOR), magnetic memory (MRAM 630), a graphics processor 622, a digital signal processor, a crypto processor, a chipset 612, an antenna 625, touchscreen display 615, touchscreen controller 665, battery 616, audio codec, video codec, power amplifier 621, global positioning system (GPS) device 640, compass 645, accelerometer, gyroscope, speaker 620, camera 641, and mass storage device (such as hard disk drive, solid-state drive (SSD), compact disk (CD), digital versatile disk (DVD), and so forth), or the like. In some exemplary embodiments, two or more of the functional blocks noted above are within IC device package 300, which includes first and second IC die on a first surface of a glass layer, a bridge IC die under the first and second IC die within an opening in the glass layer, and first and second package conductive features on a second surface of the glass layer opposite the first side, wherein the bridge IC die couples the first and second IC die with each other in first interconnects comprising solder, and couples the first and second IC die with the first package conductive features in second interconnects excluding solder, described elsewhere herein. For example, processor 604 may be implemented within circuitry in a first IC die 250, and an electronic memory (e.g., MRAM 630 or DRAM 632) may be implemented with circuitry in a second IC die 252.

Communication chips 606 may enable wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chip 606 may implement any of a number of wireless standards or protocols. As discussed, computing device 600 may include a plurality of communication chips 606. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

Example 1: In first examples, an integrated circuit (IC) device package, comprises: first and second IC die over a glass layer, the first IC die having first and second conductive features, and the second IC die having third and fourth conductive features; a third IC die under the first and second IC die within an opening in the glass layer, the third IC die having fifth conductive features on a first side and sixth conductive features on a second side opposite the first side, wherein the fifth conductive features are electrically coupled with the first and third conductive features by interconnects comprising solder; and vias electrically coupled and in direct contact with the second and fourth conductive features, the vias extending through the glass layer from the second and fourth conductive features to package conductive features.

Example 2: The IC device package of example 1, wherein the vias are first vias and the package conductive features are first package conductive features, further comprising: a dielectric layer under the glass layer; and second vias extending from the sixth conductive features through the dielectric layer to second package conductive features, wherein the sixth conductive features are electrically coupled and in direct contact with the second vias.

Example 3: The IC device package of any of examples 1 or 2, wherein the first and third conductive features have a pitch that is less than a pitch of the second and fourth conductive features.

Example 4: The IC device package of any of examples 1 through 3, wherein the fifth conductive features have a pitch that is less than a pitch of the sixth conductive features.

Example 5: The IC device package of any of examples 1 through 4, wherein the first and third conductive features have a pitch that is less than 60 microns.

Example 6: The IC device package of any of examples 1 through 5, wherein the second and fourth conductive features have a pitch that is greater than 80 microns.

Example 7: The IC device package of any of examples 1 through 6, wherein the fifth conductive features have a pitch that is less than 60 microns, and the sixth conductive features have a pitch that is greater than 80 microns.

Example 8: The IC device package of any of examples 1 through 7, wherein the third IC die electrically couples the first IC die and the second IC die.

Example 9: A system, comprising: a microprocessor, wherein the microprocessor comprises first circuitry on a first IC die having first and second conductive features; a memory coupled to the microprocessor, wherein the memory comprises second circuitry on a second IC die having third and fourth conductive features; a glass layer, wherein the first and second IC die are over the glass layer; a dielectric layer under the glass layer; a third IC die under the first and second IC die within an opening in the glass layer, the third IC die having fifth conductive features on a first side and sixth conductive features on a second side opposite the first side, wherein the fifth conductive features are electrically coupled with the first and third conductive features by first interconnects comprising solder; and vias extending from the sixth conductive features through the dielectric layer to package conductive features, wherein the sixth conductive features are electrically coupled with the vias by second interconnects, the second interconnects excluding solder.

Example 10: The system of example 9, wherein the vias are first vias and the package conductive features are first package conductive features, further comprising: second vias electrically coupled with the second and fourth conductive features by third interconnects, the second vias extending through the glass layer and through the dielectric layer to second package conductive features, wherein the third interconnects exclude solder.

Example 11: The system of any of examples 9 or 10, wherein the first and third conductive features have a pitch that is less than a pitch of the second and fourth conductive features.

Example 12: The system of any of examples 9 through 11, wherein the fifth conductive features have a pitch that is less than a pitch of the sixth conductive features.

Example 13: The system of any of examples 9 through 12, wherein the fifth conductive features have a pitch that is less than 60 microns, and the sixth conductive features have a pitch that is greater than 80 microns.

Example 14: The system of any of examples 9 through 13, further comprising: a communication bridge, wherein the communication bridge comprises the third IC die, and the communication bridge electrically couples the first IC die and the second IC die.

Example 15: The system of any of examples 9 through 14, wherein the third IC die further comprises third circuitry including transistors.

Example 16: A method for fabricating an IC device structure method comprises: receiving a workpiece comprising glass; forming an opening and a plurality of holes through the glass; placing a first IC die within the opening, the first IC die comprising first conductive features on a first side and second conductive features on a second side opposite the first side; placing second and third IC die over the first IC die, the second IC die having third and fourth conductive features on a third side, and the third IC die having fifth and sixth conductive features on a fourth side, wherein the third and fourth sides face the glass, the third and fifth conductive features are aligned with the first conductive features, and the fourth and sixth conductive features are aligned with the holes; forming first interconnects between the first and third conductive features, and between the first and the fifth conductive features, the first interconnects comprising solder; forming via metallization within the holes, the via metallization comprising vias in the glass and second interconnects, wherein the second interconnects comprise direct contacts between the via metallization and the fourth and sixth conductive features.

Example 17: The method of example 16, wherein the plurality of holes comprises first holes, the via metallization comprises first via metallization, and the vias comprise first vias, further comprising: forming a dielectric layer on the second side of the glass; forming second holes through the dielectric layer; forming second metallization within the second holes, the second metallization comprising forming second vias in the dielectric layer and second interconnects with the second conductive features, wherein the second interconnects exclude solder.

Example 18: The method of any of examples 16 or 17, wherein in the glass comprises a first footprint, the dielectric layer comprises a second footprint that is larger than the first footprint, further comprising: singulating the IC device structure through the dielectric layer in a region outside of the first footprint.

Example 19: The method of any of examples 16 through 18, wherein the forming the first interconnects comprises thermocompression bonding between the first and third conductive features, and between the first and the fifth conductive features.

Example 20: The method of any of examples 16 through 19, wherein the first IC die electrically couples the second IC die and the third IC die.

However, the above embodiments are not limited in this regard, and, in various implementations, the above embodiments may include the undertaking of only a subset of such features, undertaking a different order of such features, undertaking a different combination of such features, and/or undertaking additional features than those features explicitly listed. The scope of the disclosure should therefore be determined with reference to the appended claims, along with the full scope of equivalents to which such claims are entitled.

What is claimed is:

1. An integrated circuit (IC) device package, comprising:
first and second IC die over a glass layer, the first IC die having first and second conductive features, and the second IC die having third and fourth conductive features;
a third IC die under the first and second IC die within an opening in the glass layer, the third IC die having fifth conductive features on a first side and sixth conductive features on a second side opposite the first side, wherein the fifth conductive features are electrically coupled with the first and third conductive features by interconnects comprising solder; and
vias electrically coupled and in direct contact with the second and fourth conductive features, the vias extending through the glass layer from the second and fourth conductive features to package conductive features.

2. The IC device package of claim 1, wherein the vias are first vias and the package conductive features are first package conductive features, further comprising:
a dielectric layer under the glass layer; and
second vias extending from the sixth conductive features through the dielectric layer to second package conductive features, wherein the sixth conductive features are electrically coupled and in direct contact with the second vias.

3. The IC device package of claim 1, wherein the first and third conductive features have a pitch that is less than a pitch of the second and fourth conductive features.

4. The IC device package of claim 1, wherein the fifth conductive features have a pitch that is less than a pitch of the sixth conductive features.

5. The IC device package of claim 1, wherein the first and third conductive features have a pitch that is less than 60 microns.

6. The IC device package of claim 1, wherein the second and fourth conductive features have a pitch that is greater than 80 microns.

7. The IC device package of claim 1, wherein the fifth conductive features have a pitch that is less than 60 microns, and the sixth conductive features have a pitch that is greater than 80 microns.

8. The IC device package of claim 1, wherein the third IC die electrically couples the first IC die and the second IC die.

9. A system, comprising:
a microprocessor, wherein the microprocessor comprises first circuitry on a first IC die having first and second conductive features;
a memory coupled to the microprocessor, wherein the memory comprises second circuitry on a second IC die having third and fourth conductive features;
a glass layer, wherein the first and second IC die are over the glass layer;
a dielectric layer under the glass layer;
a third IC die under the first and second IC die within an opening in the glass layer, the third IC die having fifth conductive features on a first side and sixth conductive features on a second side opposite the first side, wherein the fifth conductive features are electrically coupled with the first and third conductive features by first interconnects comprising solder; and
vias extending from the sixth conductive features through the dielectric layer to package conductive features, wherein the sixth conductive features are electrically coupled with the vias by second interconnects, the second interconnects excluding solder.

10. The system of claim 9, wherein the vias are first vias and the package conductive features are first package conductive features, further comprising:
second vias electrically coupled with the second and fourth conductive features by third interconnects, the second vias extending through the glass layer and through the dielectric layer to second package conductive features, wherein the third interconnects exclude solder.

11. The system of claim 9, wherein the first and third conductive features have a pitch that is less than a pitch of the second and fourth conductive features.

12. The system of claim 9, wherein the fifth conductive features have a pitch that is less than a pitch of the sixth conductive features.

13. The system of claim 9, wherein the fifth conductive features have a pitch that is less than 60 microns, and the sixth conductive features have a pitch that is greater than 80 microns.

14. The system of claim 9, further comprising: a communication bridge, wherein the communication bridge comprises the third IC die, and the communication bridge electrically couples the first IC die and the second IC die.

15. The system of claim 14, wherein the third IC die further comprises third circuitry including transistors.

16. A method for fabricating an IC device structure, the method comprising:
receiving a workpiece comprising glass;
forming an opening and a plurality of holes through the glass;
placing a first IC die within the opening, the first IC die comprising first conductive features on a first side and second conductive features on a second side opposite the first side;
placing second and third IC die over the first IC die, the second IC die having third and fourth conductive features on a third side, and the third IC die having fifth and sixth conductive features on a fourth side, wherein the third and fourth sides face the glass, the third and fifth conductive features are aligned with the first conductive features, and the fourth and sixth conductive features are aligned with the holes;
forming first interconnects between the first and third conductive features, and between the first and the fifth conductive features, the first interconnects comprising solder;
forming via metallization within the holes, the via metallization comprising vias in the glass and second interconnects, wherein the second interconnects comprise direct contacts between the via metallization and the fourth and sixth conductive features.

17. The method of claim 16, wherein the plurality of holes comprises first holes, the via metallization comprises first via metallization, and the vias comprise first vias, further comprising:
forming a dielectric layer on the second side of the glass;
forming second holes through the dielectric layer;
forming second metallization within the second holes, the second metallization comprising forming second vias in the dielectric layer and second interconnects with the second conductive features, wherein the second interconnects exclude solder.

18. The method of claim 17, wherein in the glass comprises a first footprint, the dielectric layer comprises a second footprint that is larger than the first footprint, further comprising: singulating the IC device structure through the dielectric layer in a region outside of the first footprint.

19. The method of claim 16, wherein the forming the first interconnects comprises thermocompression bonding between the first and third conductive features, and between the first and the fifth conductive features.

20. The method of claim 16, wherein the first IC die electrically couples the second IC die and the third IC die.
